(19) United States
(12) Patent Application Publication
(10) Pub. No.: US 2025/0343370 A1
(43) Pub. Date: Nov. 6, 2025

(54) STAGGERED CONTACT PAD PADDLE CARD

(71) Applicant: Molex, LLC, Lisle, IL (US)

(72) Inventors: Sameer Murthy, Bangalore (IN); Rahul Mohan Doss, Lisle, IL (US); Sina Bardikalaie, Aurora, IL (US); Michael Garrison, Russellville, AR (US)

(21) Appl. No.: 19/194,079

(22) Filed: Apr. 30, 2025

(30) Foreign Application Priority Data
May 2, 2024 (IN) 202421034850

(51) Int. Cl. H01R 12/72; H01R 13/24; H01R 13/6592; H01R 13/66

(52) U.S. Cl. CPC H01R 12/721; H01R 13/2492; H01R 13/6592; H01R 13/6658

(57) ABSTRACT

Aspects of staggered contact pads on paddle cards for pluggable modules are described. An example paddle card for a pluggable module includes a mating tip at one end, a first cluster group of contact pads set back from the mating tip along a longitudinal axis of the paddle card, and a second cluster group of contact pads set back from the mating tip along the longitudinal axis. The first cluster group of contact pads includes a first inline row and a second inline row of contact pads. The second cluster group includes a third inline row and a fourth inline row of contact pads. Contact pads in the first inline row are staggered in a transverse direction from contact pads in the second inline row. Contact pads in the third inline row are staggered in a transverse direction from contact pads in the fourth inline row.

### BACKGROUND

The amount of data processed by computers, computing systems, and computing environments continues to increase. For example, data centers can include hundreds of computing and networking systems interconnected using optical cables, copper cables, and various connectors, cable assemblies, and terminations between them. The data throughput of these interconnects is high and increasing. As examples, many data centers incorporate a combination of 10 Gigabit Ethernet (10 GbE), 25 GbE, 50 GbE, and 100 GbE network interfaces and interconnects. 200 GbE, 400 GbE, and 800 GbE interconnection technology is also being developed and deployed. Other interconnection solutions rely upon 56 Gigabit per second (Gb/s), 112 Gb/s, and 224 Gb/s interconnection technologies, and interconnection technologies are being developed to support higher data rates. A range of cable assemblies are available for the data interconnects. A variety of designs exist for each cable assembly, depending on the requirements of the data communications environment in which the connectors are used.

The small form-factor pluggable (SFP) module format is a compact, hot-pluggable network interface module format used for data interconnects. An SFP interface on a computing or networking system is a modular slot for a media-specific transceiver, such as a fiber-optic or a copper cable. Cable assemblies can include SFP pluggable transceiver modules at one or both ends of a copper, fiber-optic, or other type of interconnecting cable. SFP pluggable transceiver modules can be inserted into SFP interfaces for data interconnections.

### SUMMARY

Aspects of staggered contact pads on paddle cards for pluggable modules are described. An example paddle card for a pluggable module includes a mating tip at one end, a first cluster group of contact pads set back from the mating tip along a longitudinal axis of the paddle card, and a second cluster group of contact pads set back from the mating tip along the longitudinal axis. The first cluster group of contact pads includes a first inline row and a second inline row of contact pads. The second cluster group includes a third inline row and a fourth inline row of contact pads. Contact pads in the first inline row are staggered in a transverse direction from contact pads in the second inline row. Contact pads in the third inline row are staggered in a transverse direction from contact pads in the fourth inline row.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 illustrates a perspective view of a pluggable module at one end of a cable assembly according to aspects of the present disclosure.

FIG. 2A illustrates a perspective view of a paddle card in the pluggable module and cables in the cable bundle shown in FIG. 1 according to aspects of the present disclosure.

FIG. 2B illustrates a detail view of the paddle card and cables shown in FIG. 2A according to aspects of the present disclosure.

FIG. 3A illustrates a top view of the paddle card shown in FIG. 2A according to aspects of the present disclosure.

FIG. 3B illustrates a bottom view of the paddle card shown in FIG. 2A according to aspects of the present disclosure.

FIG. 3C illustrates a top perspective view of the paddle card shown in FIG. 2A according to aspects of the present disclosure.

FIG. 3D illustrates a bottom perspective view of the paddle card shown in FIG. 2A according to aspects of the present disclosure.

FIG. 4 illustrates an example cable used in FIG. 2A, according to aspects of the present disclosure.

### DETAILED DESCRIPTION

The amount of data processed by computers, computing systems, and computing environments continues to increase. For example, data centers can include hundreds of computing and networking systems interconnected using optical cables, copper cables, and various connectors, cable assemblies, and terminations between them. The small form-factor pluggable (SFP) module format is a compact, hot-pluggable network interface module format used in data interconnects between a range of different computing systems in computing environments. SFP pluggable transceiver modules can be inserted into SFP interfaces for the data interconnects. An SFP interface on a computing or networking system is a modular slot for a media-specific transceiver, such as a copper cable or fiber-optic transceiver. Cable assemblies can include SFP pluggable transceiver modules at one or both ends of a copper, fiber-optic, or other type of interconnecting cable or cable bundle.

A range of SFP pluggable transceiver modules are currently available, including small form-factor pluggable double density (SFP-DD), compact small form-factor pluggable (cSFP), SFP+, quad small form-factor pluggable (QSFP), quad small form-factor pluggable double density (QSFP-DD), octal small form factor pluggable (OSFP), and others. SFP pluggable transceiver modules often include one or more printed circuit boards (PCBs), also called paddle cards, to which the signals carried over cables are terminated. A range of semiconductor circuit devices or chips and other circuitry mounted to the PCB or PCB. An active electrical cable (AEC) assembly can include one or more SFP pluggable transceiver modules at the free ends of cables or a cable bundle. An AEC assembly can include a PCB and one or more semiconductor chips for signal re-timing, noise reduction, signal integrity improvement, and other functions.

In the context outlined above, aspects of staggered contact pads on paddle cards for pluggable modules are described. An example paddle card for a pluggable module includes a mating tip at one end, a first cluster group of contact pads set back from the mating tip along a longitudinal axis of the paddle card, and a second cluster group of contact pads set back from the mating tip along the longitudinal axis. The first cluster group of contact pads includes a first inline row and a second inline row of contact pads. The second cluster group includes a third inline row and a fourth inline row of contact pads. Contact pads in the first inline row are staggered in a transverse direction from contact pads in the second inline row. Contact pads in the third inline row are staggered in a transverse direction from contact pads in the fourth inline row.

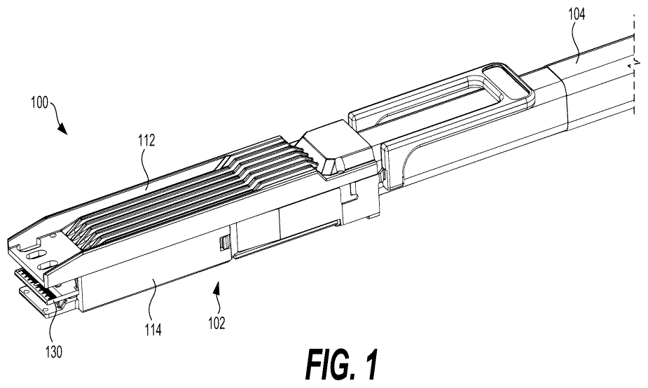

Turning to the drawings, FIG. 1 illustrates a perspective view of a pluggable module at one end of a cable assembly 100 according to aspects of the present disclosure. The cable assembly 100 is representative, not drawn to any particular scale, and is illustrated to provide context for the concepts of pluggable transceiver modules that incorporate PCBs or paddle cards with staggered rows of contact pads. The cable assembly 100 is not intended to be limited to any particular type of cable or cable assembly. The concepts of using staggered rows of contact pads in paddle cards, as described herein, are also not limited to use with PCBs or paddle cards for SFP modules. The concepts can be relied upon in a range of different assemblies including paddle cards and PCBs to accommodate cable terminations while also improving data rates and signal integrity.

The cable assembly 100 includes a pluggable transceiver module 102 (also “module 102”) at one end of a cable bundle 104. The cable assembly 100 is an example of an AEC or related type of cable assembly. The module 102, which is described in further detail below, is also representative, and the concepts described herein can be applied to a range of pluggable modules, including SFP, OSFP, SFP-DD, cSFP, SFP+, QSFP, QSFP-DD, and other types of pluggable modules.

The module 102 includes a module shell that encloses a number of components, such as a paddle card, one or more semiconductor chips and other circuitry mounted on the paddle card, and other components. The module shell includes an upper shell 112, a lower shell 114, and other components. The upper shell 112 and lower shell 114 of the module 102 can be embodied as or formed from a metal or metal alloy. In one example, the upper shell 112 and lower shell 114 can be embodied as a die-cast zinc, zinc alloy, or other metals or metal alloys and can be plated in some cases. The cable bundle 104 can include a number of cables with signal and ground or drain conductors. In one example, the cable bundle 104 includes a number of twinaxial cables, also called twinax cables. Each twinax cable can include a pair of conductors, each surrounded by a dielectric insulator or insulating material, a shield, one or more drain conductors, a jacket, and other features or components. Twinax cables can be particularly suited for use in short-range, high-speed differential data signaling applications. The cable bundle 104 can be embodied by cables other than twinax cables in some cases, including twisted pair cables, shielded twisted pair cables, single-conductor cables, shielded single-conductor cables, single-conductor coaxial cables, and other types of cables. The concepts described herein are not limited to use with any particular type or style of cable.

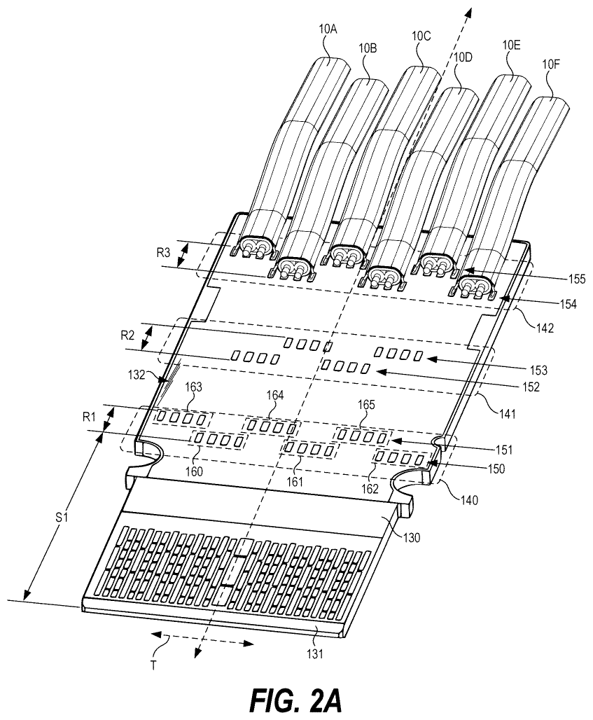

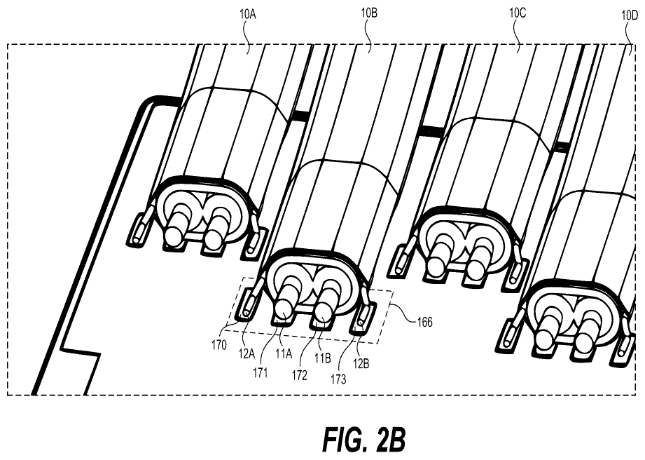

FIG. 2A illustrates a perspective view of a paddle card 130 in the pluggable module 102 and cables 10A-10F in the cable bundle 104 shown in FIG. 1. The paddle card 130 extends in a longitudinal axis “L” as shown in FIG. 2A. A transverse direction “T” is also identified in FIG. 2A, and the transverse direction “T” is orthogonal to the direction of the longitudinal axis “L.” The paddle card 130 is representative, not drawn to any particular scale, and is illustrated to provide context for the concepts of staggered rows of contact pads on PCBs and paddle cards. The paddle card 130 is not intended to be limited to any particular type of paddle card or PCB. The concepts of using staggered rows of contact pads in paddle cards, as described herein, are also not limited to use with any particular type or style of paddle card or PCB.

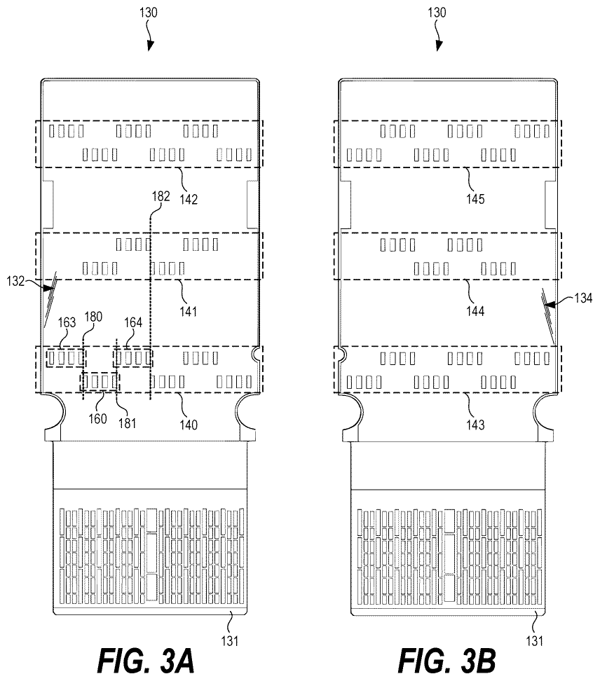

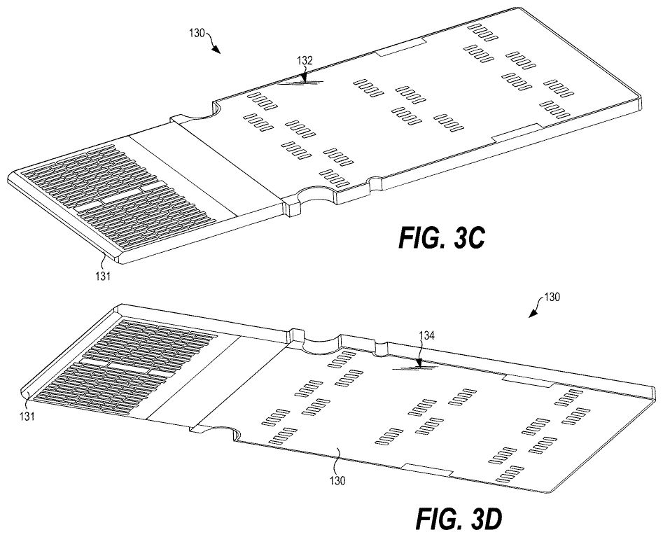

The paddle card 130 includes a mating tip 131 at one end, a top surface 132, and a bottom surface 134 (see FIG. 3B). The paddle card 130 can be embodied as a printed circuit board including a laminated stack of metal layers and dielectric insulating material. One or more semiconductor chips and other circuit components (not shown) can be electrically coupled to and mounted on the paddle card 130 and electrically interconnected by metal traces of the paddle card 130. The mating tip 131 of the paddle card 130 includes an arrangement of contact pads on the top surface 132 and on the bottom surface 134. The mating tip 131 can be inserted into a connector for establishing electrical interconnections between terminals in the connector and the contact pads, as would be understood in the field.

A number of shielded cables, such as the cables 10A-10F, among others, have conductors that are electrically coupled and terminated to the paddle card 130. FIG. 2A does not illustrate all the cables that can be terminated to the top surface 132 of the paddle card 130, and additional cables can also be terminated to the bottom surface 134 of the paddle card 130. Each of the cables 10A-10F is a twinax cable in the example shown. Signal conductors in the cables 10A-10F are electrically coupled and terminated to signal contact pads of the paddle card 130. Additionally, ground or drain conductors in the cables 10A-10F are electrically coupled and terminated to ground contact pads on the paddle card 130. As described in further detail below, the signal and ground contact pads are arranged in cable termination contact pad groups, and one cable termination contact pad group can include includes a pair of signal contact pads and a pair of ground contact pads. Two, three, four, or more contact pad groups can be arranged into inline rows of contact pads, and two or more inline rows can be arranged in a cluster group of contact pads on the paddle card 130. The inline rows of contact pads in a cluster group can be staggered with respect to each other. The paddle card 130 also includes cluster groups of contact pads on both the top surface 132 and the bottom surface 134. These and other aspects are described below.

In some cases, a subset of the cables 10A-10F, among others, that are terminated to the paddle card 130 can be relied upon for data reception (e.g., data RX) and another subset of the cables can be relied upon for data transmission (e.g., data TX). The pitch between the longitudinal axis of adjacent cables in a row can be the same in some cases, regardless of whether the cables are relied upon for RX or TX. In other cases, the pitch between the longitudinal axis of cables can vary in the same row depending on whether or not the cables are relied upon for RX or TX.

The paddle card 130 includes a number of cluster groups of contact pads on the top surface 132. The paddle card 130 includes the cluster groups 140-142 in the example shown. Each cluster group includes a number of inline rows of contact pads. For example, the cluster group 140 includes a first inline row 150 of contact pads and a second inline row 151 of contact pads. Similarly, the cluster group 141 includes inline rows 152 and 153 of contact pads, and the cluster group 142 includes inline rows 154 and 155 of contact pads. Thus, each of the cluster groups 140-142 includes two inline rows of contact pads in the example shown. Cluster groups of greater than two inline rows can be relied upon, however, and single inline rows can also be relied upon in other examples. In the cluster group 140, the contact pads in the first inline row 150 of the contact pads are staggered in the transverse direction “T” from the contact pads in the second inline row 151 of the contact pads. The inline rows of contact pads are also staggered as compared to each other in the cluster group 141 and in the cluster group 142.

One or more rows among two different cluster groups can also be staggered as compared to each other. For example, the row 151 in the cluster group 140 is staggered in the transverse direction “T” as compared to the row 152 in the cluster group 141. The row 153 in the cluster group 141 is also staggered as compared to the row 154 in the cluster group 142, and other examples of staggered rows between two different cluster groups are shown in FIG. 2A. As another example, if the cluster group 140 included only the row 150 and not the row 151 and the cluster group 141 included only the row 153 and not the row 152, the remaining rows in the cluster groups 140 and 141 would still be staggered with respect to each other.

The cluster group 140 is set back a distance S1 from a front edge of the mating tip 131 along the longitudinal axis “L” of the paddle card 130 to within a surface range R1 of the paddle card 130. The cluster group 141 is set back a different distance (i.e., a distance larger than S1+R1) from the front edge of the mating tip 131 along the longitudinal axis “L” of the paddle card 130 to within a surface range R2 of the paddle card 130. The cluster group 142 is set back a different distance (i.e., a distance larger than S1+R1+R2) from the front edge of the mating tip 131 along the longitudinal axis “L” of the paddle card 130 to within a surface range R3 of the paddle card 130. In the example shown, the cluster groups 140-142 are equally spaced apart from each other, as measured along the longitudinal axis “L.” Different spacings can be relied upon between the cluster groups 140-142 in other examples, however. The paddle card 130 can also include additional or fewer numbers of cluster groups of contact pads in other examples.

Referring to the cluster group 140, each of the inline rows 150 and 151 includes cable termination contact pad groups. The inline row 150 includes termination contact pad groups 160-162, and the inline row 151 includes termination contact pad groups 163-165, for a total of six (6) termination contact pad groups in the cluster group 140. As noted above, the termination contact pad groups 160-162 are staggered in the transverse direction “T” as compared to the termination contact pad groups 163-165. Each of the termination contact pad groups 160-165 includes four contact pads, including an outer pair of ground or drain contact pads and an inner pair of signal contact pads. The signal and drain conductors of one twinax cable can be electrically coupled (e.g., soldered, sintered, etc.) to the contact pads of one termination contact pad group 160-165.

In the cluster group 141, the inline row 152 includes two (2) termination contact pad groups, and the inline row 153 includes two (2) termination contact pad groups, for a total of four (4) termination contact pad groups in the cluster group 141. In the cluster group 142, the inline row 154 includes three (3) termination contact pad groups, and the inline row 155 includes three (3) termination contact pad groups, for a total of six (6) termination contact pad groups in the cluster group 142.

Referring again to the cluster group 140, an edge of a drain contact pad in the cable termination contact pad group 163 is aligned with an edge of a drain contact pad in the cable termination contact pad group 160, as also identified by the dotted line 180 in FIG. 3A. An edge of another drain contact pad in the cable termination contact pad group 160 is aligned with an edge of a drain contact pad in the cable termination contact pad group 164, as identified by the dotted line 181 in FIG. 3A, and so on. Edges of drain contact pads can also be aligned among different cluster groups, and the dotted line 182 identifies the alignment of drain contact pad edges among two rows in the cluster groups 140 and 141. In other cases, the edges of drain contact pads can be staggered among two different rows in one cluster group, staggered among rows in two cluster groups, or both staggered among rows in the same cluster group and between two different cluster groups.

The cables 10A-10F are electrically coupled to respective termination contact pad groups in the cluster group 142, as shown in FIG. 2A. Cables similar to the cables 10A-10F can also be electrically coupled to the contact pad groups in the cluster groups 140 and 141, although not shown in FIG. 2A. Overall, the paddle card 130 includes sixteen (16) termination contact pad groups on the top surface 132, and sixteen (16) twinax cables can be electrically terminated to the top surface 132 of the paddle card 130.

FIG. 2B illustrates a detail view of the paddle card 130 and cables 10A-10D shown in FIG. 2A. The termination contact pad group 166 in the inline row 154 (see FIG. 2A) is also identified in FIG. 2B. The cable 10B, as an example, includes two signal conductors 11A and 11B for data communication. The signal conductors 11A and 11B can be embodied as copper conductors, copper-clad steel conductors, or conductors formed from other metals. The conductors can include an outer-surface plating of silver or other metals in some cases. As examples, the conductors can range in gauge, such as between 22-34 AWG, although conductors of other gauges can be relied upon in twinax cables. Data signals can be differentially coupled to the signal conductors 11A and 11B, and the cable 10A can be used to communicate data using a range of modulation and signaling techniques. The conductors 11A and 11B are electrically coupled to signal contact pads 171 and 172 on the top surface 132 of the paddle card 130. Within the cable 10B, the signal conductors 11A and 11B are surrounded by a core of dielectric insulating material, such as a solid or low-density polyolefin, polyethylene (PE), polytetrafluoroethylene (PTFE), fluoropolymer, or other plastic or insulating material.

The cable 10B also includes a shield around the dielectric insulating material, drain conductors 12A and 12B, and an outer jacket. The shield can be embodied as a relatively thin layer of conductive material, such as aluminum, copper, or other conductive shield layer, that is wrapped around and covers the outer surface of the dielectric insulating material. The drain conductors 12A and 12B can be embodied as aluminum, copper, or other metal conductors. The drain conductors 12A and 12B can range in gauge and can be a larger or smaller gauge than the signal conductors 11A and 11B in some cases. The drain conductors 12A and 12B contact and are electrically coupled with the shield 14. The drain conductors 12A and 12B are also electrically coupled to respective ground contact pads 170 and 173 on the top surface 132 of the paddle card 130.

FIG. 3A illustrates a top view of the paddle card 130 shown in FIG. 2A, FIG. 3B illustrates a bottom view of the paddle card 130 shown in FIG. 2A, FIG. 3C illustrates a top perspective view of the paddle card 130, and FIG. 3D illustrates a bottom perspective view of the paddle card 130. Referring to FIG. 3B, the paddle card 130 includes a number of cluster groups of contact pads on the bottom surface 134. The paddle card 130 includes the cluster groups 143-145 in the example shown. Each cluster group includes a number of inline rows of contact pads. For example, the cluster group 143 includes two inline rows of contact pads. Similarly, the cluster groups 144 and 145 also include two inline rows of contact pads each. Cluster groups of greater than two inline rows can be relied upon, however, and single inline rows can also be relied upon in other examples. In the cluster group 143, the two inline rows of contact pads are staggered in the transverse direction “T” with respect to each other. The inline rows of contact pads are also staggered as compared to each other in the cluster group 144 and in the cluster group 145. Each of the inline rows of contact pads on the bottom surface 134 of the paddle card 130 includes multiple cable termination contact pad groups, similar to the top surface 132. Overall, the paddle card 130 includes sixteen (16) termination contact pad groups on the bottom surface 134, and sixteen (16) twinax cables can be electrically terminated to the bottom surface 134 of the paddle card 130. In total, thirty-two (32) twinax cables can be terminated to the top and bottom surfaces 132 and 134 of the paddle card 130 in the example shown, although other paddle cards can accommodate greater or fewer terminations.

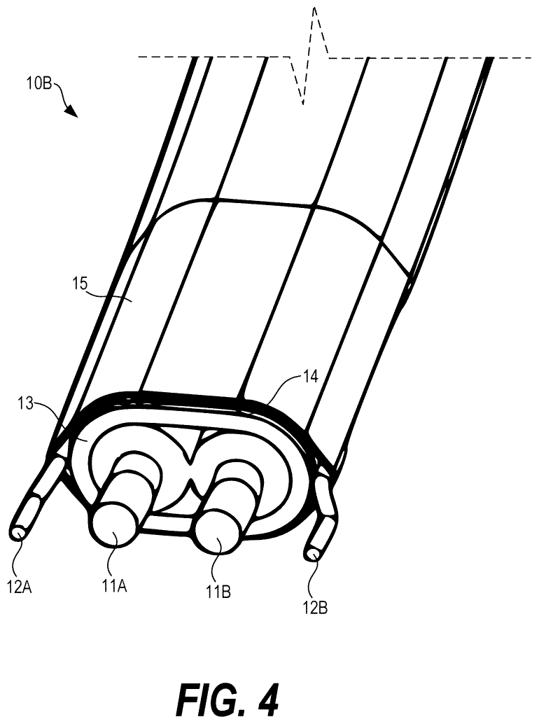

FIG. 4 illustrates the cable 10B shown in FIG. 2A, according to aspects of the present disclosure. As noted above, the cable 10A includes two signal conductors 11A and 11B, a core of dielectric insulating material 13, a shield 14 around the dielectric insulating material 13, drain conductors 12A and 12B, and an outer jacket 15. The shield 14 can be embodied as a relatively thin layer of conductive material, such as aluminum, copper, or other conductive shield layer, that is wrapped around and covers the outer surface of the dielectric insulating material 13.

Terms such as “top,” “bottom,” “side,” “front,” “back,” “right,” and “left” are not intended to provide an absolute frame of reference. Rather, the terms are relative and are intended to identify certain features in relation to each other, as the orientation of structures described herein can vary. The terms “comprising,” “including,” “having,” and the like are synonymous, are used in an open-ended fashion, and do not exclude additional elements, features, acts, operations, and so forth. Also, the term “or” is used in its inclusive sense, and not in its exclusive sense, so that when used, for example, to connect a list of elements, the term “or” means one, some, or all of the elements in the list.

Combinatorial language, such as “at least one of X, Y, and Z” or “at least one of X, Y, or Z,” unless indicated otherwise, is used in general to identify one, a combination of any two, or all three (or more if a larger group is identified) thereof, such as X and only X, Y and only Y, and Z and only Z, the combinations of X and Y, X and Z, and Y and Z, and all of X, Y, and Z. Such combinatorial language is not generally intended to, and unless specified does not, identify or require at least one of X, at least one of Y, and at least one of Z to be included.

The terms “about” and “substantially,” unless otherwise defined herein to be associated with a particular range, percentage, or related metric of deviation, account for at least some manufacturing tolerances between a theoretical design and manufactured product or assembly, such as the geometric dimensioning and tolerancing criteria described in the American Society of Mechanical Engineers (ASME®) Y14.5 and the related International Organization for Standardization (ISO®) standards. Such manufacturing tolerances are still contemplated, as one of ordinary skill in the art would appreciate, although “about,” “substantially,” or related terms are not expressly referenced, even in connection with the use of theoretical terms, such as the geometric “perpendicular,” “orthogonal,” “vertex,” “collinear,” “coplanar,” and other terms.

The above-described embodiments of the present disclosure are merely examples of implementations to provide a clear understanding of the principles of the present disclosure. Many variations and modifications can be made to the above-described embodiments without departing substantially from the spirit and principles of the disclosure. In addition, components and features described with respect to one embodiment can be included in another embodiment. All such modifications and variations are intended to be included herein within the scope of this disclosure.

1. A paddle card for a pluggable module, comprising:
a mating tip at one end;
a first cluster group of contact pads set back from a front edge of the mating tip along a longitudinal axis of the paddle card to within a surface range of the paddle card; and
a second cluster group of contact pads set back from the front edge of the mating tip along the longitudinal axis to within a second surface range of the paddle card, wherein:
the first cluster group comprises a first inline row and a second inline row of contact pads at a top surface of the paddle card;
the second cluster group comprises a third inline row and a fourth inline row of contact pads at the top surface of the paddle card;
contact pads in the first inline row are staggered in a transverse direction from contact pads in the second inline row; and
contact pads in the third inline row are staggered in the transverse direction from the fourth inline row.

2. The paddle card according to claim 1, wherein the first cluster group of contact pads comprises a plurality of cable termination contact pad groups.

3. The paddle card according to claim 1, wherein the first cluster group of contact pads comprises a plurality of cable termination contact pad groups in the first inline row and a second plurality of cable termination contact pad groups in the second inline row.

4. The paddle card according to claim 1, wherein:
the first cluster group of contact pads comprises a first cable termination contact pad group in the first inline row and a second cable termination contact pad group in the second inline row; and
an edge of a drain contact pad in the first cable termination contact pad group is aligned with an edge of a drain contact pad in the second cable termination contact pad group.

5. The paddle card according to claim 1, wherein contact pads in the first inline row are aligned along the longitudinal axis with contact pads in the third inline row.

6. The paddle card according to claim 1, wherein contact pads in the second inline row are aligned along the longitudinal axis with contact pads in the fourth inline row.

7. The paddle card according to claim 1, wherein contact pads in the first inline row are not aligned along the longitudinal axis with contact pads in the fourth inline row.

8. The paddle card according to claim 1, wherein the first cluster group of contact pads comprises more contact pads than the second cluster group of contact pads.

9. The paddle card according to claim 1, wherein:
the first cluster group of contact pads comprises a plurality of cable termination contact pad groups; and
the second cluster group of contact pads comprises a second plurality of cable termination contact pad groups.

10. The paddle card according to claim 1, further comprising:
a third cluster group of contact pads set back from the front edge of the mating tip along the longitudinal axis of the paddle card to within a third surface range of the paddle card, wherein:
the third cluster group of contact pads comprises a fifth inline row of contact pads and a sixth inline row of contact pads; and
contact pads in the fifth inline row are staggered in the transverse direction from contact pads in the sixth inline row of the contact pads.

11. A pluggable transceiver module, comprising:
a printed circuit board (PCB) comprising a mating tip at one end, a first cluster group of contact pads set back from a front edge of the mating tip along a longitudinal axis of the PCB, and a second cluster group of contact pads set back from the front edge of the mating tip along the longitudinal axis to within a second surface range of the PCB, wherein:
the first cluster group comprises a first inline row and a second inline row of contact pads at a top surface of the PCB;
the second cluster group comprises a third inline row and a fourth inline row of contact pads at the top surface of the PCB;
contact pads in the first inline row are staggered in a transverse direction from contact pads in the second inline row; and
contact pads in the third inline row are staggered in the transverse direction from the fourth inline row.

12. The pluggable transceiver module according to claim 11, wherein the first cluster group of contact pads comprises a plurality of cable termination contact pad groups.

13. The pluggable transceiver module according to claim 11, wherein the first cluster group of contact pads comprises a plurality of cable termination contact pad groups in the first inline row and a second plurality of cable termination contact pad groups in the second inline row.

14. The pluggable transceiver module according to claim 11, wherein:
the first cluster group of contact pads comprises a first cable termination contact pad group in the first inline row and a second cable termination contact pad group in the second inline row; and
an edge of a drain contact pad in the first cable termination contact pad group is aligned with an edge of a drain contact pad in the second cable termination contact pad group.

15. The pluggable transceiver module according to claim 11, wherein contact pads in the first inline row are aligned along the longitudinal axis with contact pads in the third inline row.

16. The pluggable transceiver module according to claim 11, wherein contact pads in the second inline row are aligned along the longitudinal axis with contact pads in the fourth inline row.

17. The pluggable transceiver module according to claim 11, wherein contact pads in the first inline row are not aligned along the longitudinal axis with contact pads in the fourth inline row.

18. The pluggable transceiver module according to claim 11, wherein the first cluster group of contact pads comprises more contact pads than the second cluster group of contact pads.

19. The pluggable transceiver module according to claim 11, wherein:
the first cluster group of contact pads comprises a plurality of cable termination contact pad groups; and
the second cluster group of contact pads comprises a second plurality of cable termination contact pad groups.

20. The pluggable transceiver module according to claim 11, further comprising:
a third cluster group of contact pads set back from the front edge of the mating tip along the longitudinal axis of the PCB, wherein:
the third cluster group of contact pads comprises a fifth inline row of contact pads and a sixth inline row of contact pads; and
contact pads in the fifth inline row are staggered in the transverse direction from contact pads in the sixth inline row of the contact pads.
